(19) United States
(12) Patent Application Publication
(10) Pub. No.: US 2013/0043953 A1
(43) Pub. Date: Feb. 21, 2013

(54) METHODS, CIRCUITS AND SYSTEMS FOR REGULATING THE OUTPUT POWER OF A TRANSMISSION SYSTEM

(71) Applicant: Solon Jose Spiegel, Tel Aviv (IL)

(72) Inventor: Solon Jose Spiegel, Tel Aviv (IL)

(73) Assignee: RIO SYSTEMS LTD., Givat Shmuel (IL)

(21) Appl. No.: 13/214,192

(22) Filed: Aug. 21, 2011

(51) Int. Cl. H03F 3/04

(52) U.S. Cl. 330/297

(57) ABSTRACT

Disclosed are methods, circuits and systems for regulating the output power of a transmission system. There may be provided a power amplifier (“PA”) adapted to operate across a range of supply voltages. The PA may operate under different bias profiles. There may be provided power amplifier regulation circuitry which may include a PA bias profile generator adapted to generate one or more bias profiles, wherein a given bias profile is associated with a given bias signal for the PA. A bias profile associated with a given bias signal for a given PA may include one or more PA parameters or settings to be applied to the given PA when it is operating with the given bias signal.

### FIELD OF THE INVENTION

Some embodiments relate generally to the field of voltage regulators and power circuits and, more particularly, to methods, circuits and systems for regulating the output power of a transmission system.

### BACKGROUND

Electronic circuits, ranging from simple operational amplifier circuits to large processor-driven systems, require a direct current (DC) input voltage. Whether the DC input voltage is in the range of microvolts or megavolts, it has to be stable for reliable circuit performance. For stable DC input voltage, the voltage level must remain at a constant level with minimal noise and with minimal alternating current (AC) ripple voltage.

Wireless communication has rapidly evolved over the past decades. Even today, when high performance and high bandwidth wireless communication equipment is made available there is demand for even higher performance at higher data rates, which may be required by more demanding applications. Modern Radio frequency (RF) communication systems demand complex modulation and coding schemes (e.g. CDMA, QPSK, QAM, QPSK/OFDM, QAM/OFDM, etc.) for increased bandwidth efficiency (e.g. greater than 1 bps/Hz for high data rate broadband communication systems).

Transmission systems utilizing polar modulation can modulate signals based on the instantaneous polar coordinates (e.g. amplitude (r) and phase (Θ) of a given input RF data signal. Design methods, such as envelope tracking (i.e. modulating the supply voltage of the amplifier corresponding to the signal envelope) may increase the power efficiency of the transmission system. Additional design methods, such as envelope elimination and restoration (e.g. eliminating the envelope of the signal using a limiter while extracting amplitude information, amplifying the amplitude and phase of the signal separately and recombining the amplitude and phase to restore the signal) may utilize power efficient switched-mode amplifiers for power efficient amplification. However, while maintaining linearity of the switched mode amplifier (e.g. for maintain a high level of signal quality), power efficiency can be lost.

Wireless communication circuits and systems rely on RF power amplifier circuits to provide the signal amplification needed to transmit a plurality of RF signals over varying distances and with varying signal strength. To change signal strength and maintain power efficiency at optimum levels, the supply voltage being delivered to the amplifier must be adjusted. In many modern wireless communication devices (e.g. mobile phones, smart phones, tablet computers, laptop computers, etc.), a single RF amplifier may process the varying signals being transmitted and received by the device (e.g. WIFI, Edge, CDMA, GPRS, UMTS, HSPA, WiMAX, etc. . . . ).

Maintaining an energy efficient power levels regulation of transmission systems is challenging. In closed loop power control (CLPC) systems, there are an increased number of components dedicated to output power detection and regulation. Furthermore, the output signal of a CLPC system suffers from attenuation due to the output signal detection components.

Open loop power control (OLPC) systems may be more energy efficient since there are no components associated with a CLPC feedback system. A disadvantage, however, of OLPC schemes is a variation of output power based on external conditions (e.g. temperature) and process variations.

To maintain power efficient transmission architectures across a wide range of power control, the operation point and supply voltage of the RF power amplifier should vary according to the required output level. As the output power level is adjusted, the operation point of the power amplifier should also be adjusted with variable biasing signals. For a given RF power amplifier architecture, a biasing signal and the supply voltage should be selected for optimal power efficiency.

There is thus a need in the field of voltage regulators and power control circuits for improved methods, circuits and systems for regulating the output power of a transmission system.

### SUMMARY OF THE INVENTION

The present invention includes methods, circuits and systems for regulating the output power of a transmission system. According to some embodiments, there may be provided a power amplifier (“PA”) adapted to operate across a range of supply voltages. The PA may operate under different bias profiles. There may be provided power amplifier regulation circuitry which may include a PA bias profile generator adapted to generate one or more bias profiles, wherein a given bias profile is associated with a given bias signal for the PA. A bias profile associated with a given bias signal for a given PA may include one or more PA parameters or settings to be applied to the given PA when it is operating with the given bias signal.

According to some embodiments of the present invention, the PA bias profile generator may generate a biasing signal profile dynamically selected from a set of predetermined biasing signal profiles. Dynamic selection of the biasing current profile may be based on a PA supply voltage control signal. According to further embodiments of the present invention, a PA may operate with substantially consistent power efficiency over the greatest range of supply voltages when dynamically selecting a biasing signal.

According to some embodiments of the present invention, stages of the PA may be biased with a biasing signal described by the bias profile. According to further embodiments of the present invention, a driver stage and a power stage of the PA may be biased according to a substantially similar bias profile.

According to some embodiments of the present invention, the biasing signal described by the biasing profile may be in proportion to a control signal of the PA. The PA control signal may indicate an expected output signal power, and may control a variable PA voltage supply. As the PA voltage supply is adjusted, the variable PA biasing signal may be proportionally adjusted and applied to the PA stages to maintain a substantially consistent operating point.

According to some embodiments of the present invention, a biasing signal profile generator may generate a reference biasing signal that maintains a fixed relationship to the PA control signal. According to further embodiments of the present invention, a biasing signal profile may produce a reference biasing signal that maintains a linear relationship to the PA control signal. According to further embodiments of the present invention, a biasing signal profile may produce a reference biasing signal that maintains an exponential relationship to the PA control signal. According to yet further embodiments of the present invention, a biasing signal profile may produce a reference biasing signal that maintains an arbitrary relationship to the PA control signal. The arbitrary relationship between the reference biasing signal and the PA control signal may be maintained by a translinear circuit with some defined input-to-output relationship.

According to some embodiments of the present invention, a PA operating using the biasing current profiles may operate with substantially consistent power efficiency over a given range of supply voltages. A PA operating with an exponential biasing current profile may operate with substantially consistent power efficiency over the greatest range of supply voltages.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a block diagram of an open loop RF power amplifier control system according to some embodiments of the present invention;

FIGS. 2A and 2B are block diagrams of closed loop RF power amplifier control systems according to some embodiments of the present invention;

FIG. 3A is an illustration of a bias profile generator according to some embodiments of the present invention;

FIGS. 3Bi and 3Bii are circuit diagrams for exponential differential currents generators for a current mirror and/or a translinear circuit, according to some embodiments of the present invention;

FIG. 4A is a functional block diagram of a regulated RF power amplifier according to some embodiments of the present invention;

FIG. 4B is a circuit diagram of a bias unit according to some embodiments of the present invention;

FIG. 5A is a table of reference current profiles for biasing the driver and power stages of a power amplifier according to some embodiments of the present invention; and

FIGS. 5B-5D are experimental charts comparing reference current profiles for biasing the driver and power stages of a power amplifier according to some embodiments of the preset invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION

In the following detailed description, numerous specific details are set forth in order to provide a thorough understanding of some embodiments. However, it will be understood by persons of ordinary skill in the art that some embodiments may be practiced without these specific details. In other instances, well-known methods, procedures, components, units and/or circuits have not been described in detail so as not to obscure the discussion.

Unless specifically stated otherwise, as apparent from the following discussions, it is appreciated that throughout the specification discussions utilizing terms such as “processing”, “computing”, “calculating”, “determining”, or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices. In addition, the term “plurality” may be used throughout the specification to describe two or more components, devices, elements, parameters and the like.

It should be understood that some embodiments may be used in a variety of applications. Although embodiments of the invention are not limited in this respect, one or more of the methods, devices and/or systems disclosed herein may be used in many applications, e.g., civil applications, military applications, medical applications, commercial applications, or any other suitable application. In some demonstrative embodiments the methods, devices and/or systems disclosed herein may be used in the field of consumer electronics, for example, as part of any suitable television, video Accessories, Digital-Versatile-Disc (DVD), multimedia projectors, Audio and/or Video (A/V) receivers/transmitters, gaming consoles, video cameras, video recorders, portable media players, cell phones, mobile devices, and/or automobile A/V accessories. In some demonstrative embodiments the methods, devices and/or systems disclosed herein may be used in the field of Personal Computers (PC), for example, as part of any suitable desktop PC, notebook PC, monitor, and/or PC accessories.

According to some embodiments of the present invention, there may include a variable power amplifier (PA) module comprising: a supply power modulator adapted to modulate supply power, within a defined range, to a power amplifier circuit responsive to a control signal; and a bias profile generator circuit adapted to apply one or more biasing signals to one or more transistors within the power amplifier circuit such that a power efficiency level of the power amplifier circuit may remain substantially stable across the defined range.

According to some embodiments of the present invention, one or more biasing signals may be biasing voltages. According to further embodiments of the present invention, the biasing voltages may be applied to one or more FET transistors within the power amplifier circuit.

According to some embodiments of the present invention, one or more biasing signals may be biasing currents. According to further embodiments of the present invention, the biasing currents may be applied to one or more BJT transistors within the power amplifier circuit.

According to some embodiments of the present invention, the bias profile generator circuit may be further adapted to apply one or more biasing signals in proportion to the supply power modulator control signal. According to further embodiments of the present invention, the proportion may be a fixed value. According to further embodiments of the present invention, the proportion may be a linear proportion. According to further embodiments of the present invention, the proportion may be an exponential proportion. According to some embodiments of the present invention, the bias profile generator circuit may further comprise a trans-linear circuit. According to further embodiments of the present invention, the proportion may be a high degree polynomial function proportion.

According to some embodiments of the present invention, the supply power modulator may be further adapted to modulate the supply power in a closed loop configuration. According to some embodiments of the present invention, the supply power modulator may be further adapted to modulate the supply power in an open loop configuration.

According to some embodiments of the present invention, there may include a bias profile generator circuit adapted to apply one or more biasing signals to one or more transistors within a power amplifier circuit such that a power efficiency level of the power amplifier circuit may remain substantially stable across the defined range.

According to some embodiments of the present invention, the one or more biasing signals may be biasing voltages. According to further embodiments of the present invention, the biasing voltages may be applied to one or more FET transistors within the power amplifier circuit.

According to some embodiments of the present invention, the one or more biasing signals may be biasing currents. According to further embodiments of the present invention, the biasing currents may be applied to one or more BJT transistors within the power amplifier circuit.

According to some embodiments of the present invention, the bias profile generator may be further adapted to apply one or more biasing signals in proportion to the supply power modulator control signal. According to further embodiments of the present invention, the proportion may be a fixed value. According to further embodiments of the present invention, the proportion may be a linear proportion. According to further embodiments of the present invention, the proportion may be an exponential proportion. According to some embodiments of the present invention, the bias profile generator may further comprise a trans-linear circuit. According to further embodiments of the present invention, the proportion may be a high degree polynomial function proportion.

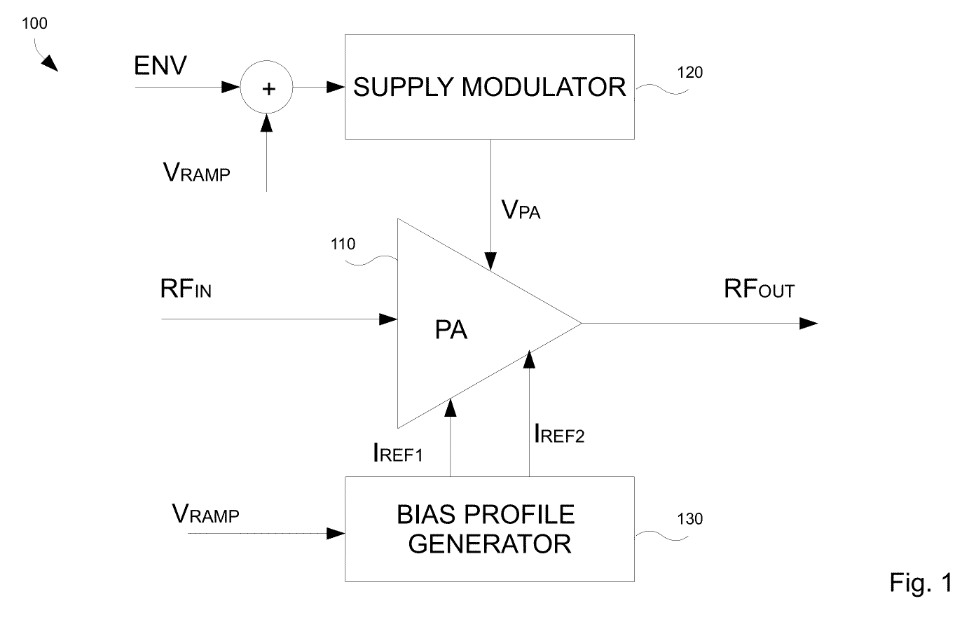

Now turning to FIG. 1, there is shown a block diagram of an open loop RF power amplifier control system (100) according to some embodiments of the present invention. According to some embodiments of the present invention, a power amplifier (110) may amplify an input RF signal. The power amplifier (110) may be an amplifier from any class of amplifier (e.g. A, B, AB, C, D, E, and/or F) and may operate in the linear region (e.g. reducing distortion at the cost of some power efficiency). According to further embodiments of the present invention, the amplification level of the power amplifier (110) may be adjustable and may be based on a supply voltage (V_{PA}) received from a functionally associated supply modulator (120). The supply modulator (120) may modulate the supply voltage based on an envelope characteristic (e.g. signal envelope variations) of the modulating signal and/or an output signal level control signal (V_{RAMP}). According to further embodiments of the present invention, the supply modulator (120) may be a linear regulator (e.g. an active voltage regulator operating in the linear region) and/or a switching regulator (e.g. a transistor operating outside of its active region). According to further embodiments of the present invention, the supply modulator (120) may be designed to provide a sufficient bandwidth for minimum envelope signal distortion, while maintaining substantially high power efficiency.

According to some embodiments of the present invention, the power amplifier control system may include a bias profile generator (130) to input programmable bias signals (i.e. current sources I_{REF1} and I_{REF2}) to the RF signal amplification components, circuits and/or devices. According to further embodiments of the present invention, programmable bias signals may be voltage sources (e.g. V_{REF1} and V_{REF2}) when components in the power amplifier (and transmission system) are voltage biased. Programmable bias signals may adjust a bias point of the amplifier components, circuits and/or devices

According to some embodiments of the present invention, the input bias currents I_{REF1} and I_{REF2} may be generated by the bias profile generator (130), wherein a magnitude of the input bias currents may be inversely proportional to a power amplifier input signal magnitude. According to further embodiments of the invention, the bias profile generator may generate bias currents in proportion with an output signal level control signal (V_{RAMP}), wherein a magnitude of the input bias currents may be directly proportional to the control signal.

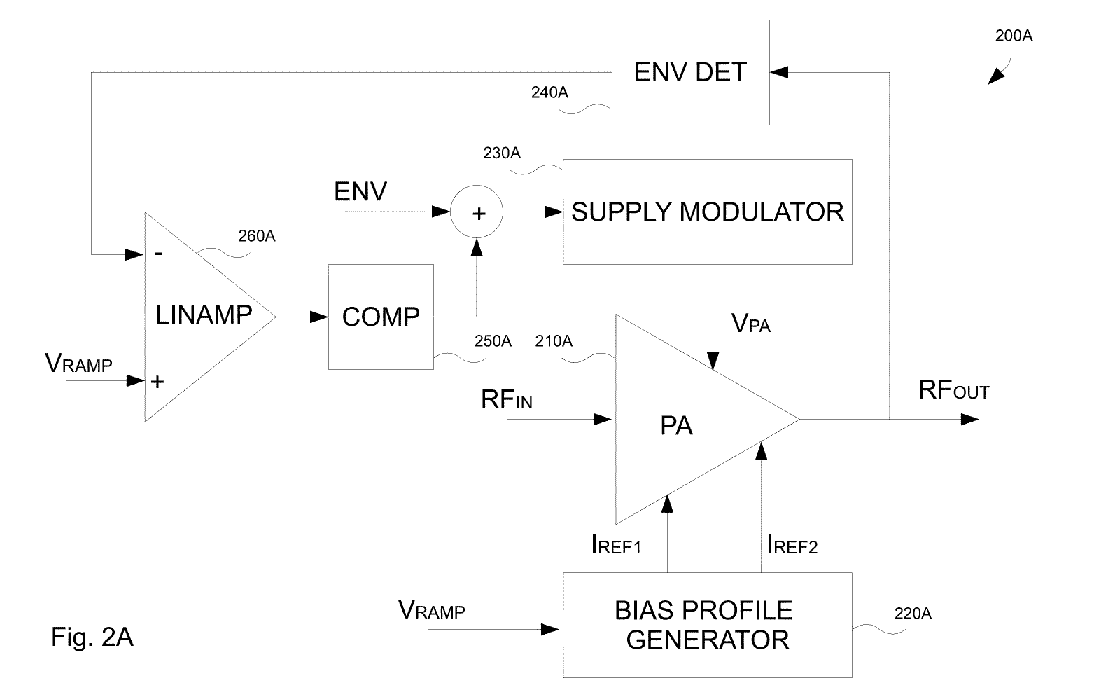

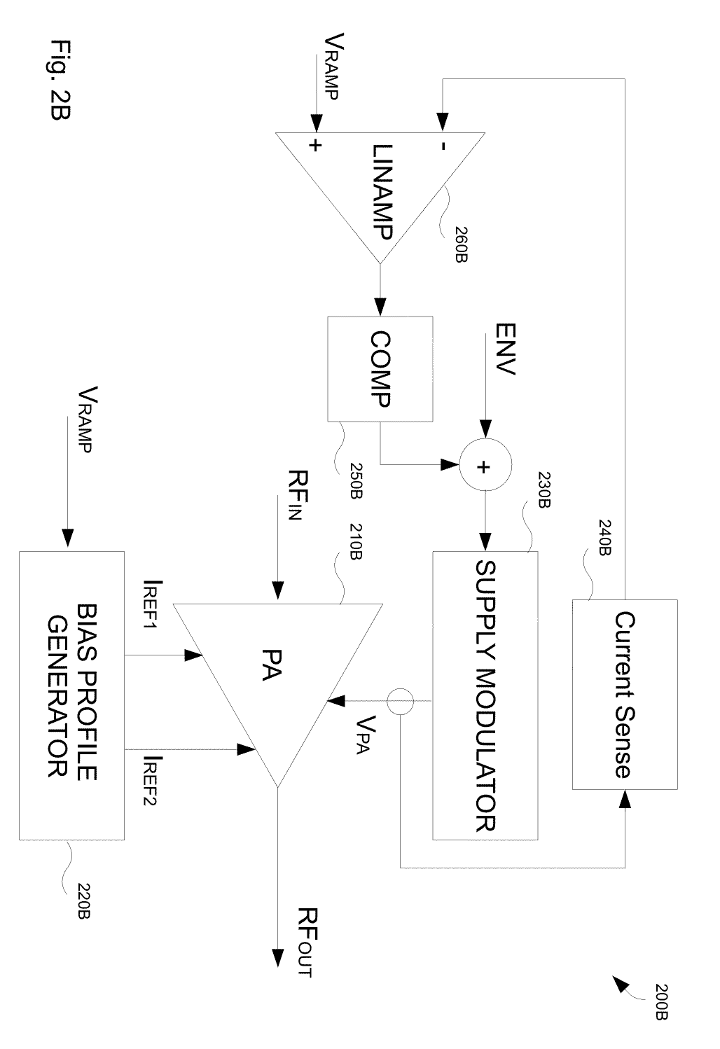

Now turning to FIG. 2A, there is shown a block diagram of a closed loop RF power amplifier control system (200A) according to some embodiments of the present invention.

According to some embodiments of the present invention, an amplification gain of a power amplifier (210A) may be controlled by a variable supply modulator (230A). The gain of the power amplifier may be substantially proportional to a voltage output from the supply modulator (V_{PA}). According to further embodiments of the present invention, the voltage output from the supply modulator (V_{PA}) may be based on a comparison of an input voltage and a detected system output voltage. The system output voltage may be determined by an envelope detector (240A), adapted to determine a peak voltage level (e.g. an amplitude) of an envelope of an amplitude modulated output signal. According to further embodiments of the present invention, a time constant may be associated with the low pass filter characteristics of the envelope detector (240A).

According to further embodiments of the present invention, the determined peak voltage level may be input to a linear amplifier (260A) as a differential input, along with an output signal level control signal (V_{RAMP}). According to further embodiments of the present invention, a compensation unit (250A) may be utilized to increase the phase margin of the linear amplifier (260A) output signal by introducing zeros into the open loop transfer function formed by compensation unit (250A), variable supply modulator (230A), power amplifier (210A), envelope detector (240A) and linear amplifier (260A). Increasing the phase margin may substantially increase the stability of the closed loop power control sub-system.

According to some embodiments of the present invention, the power amplifier control system may include a bias profile generator (220A) to input programmable bias signals (i.e. current sources I_{REF1} and I_{REF2}) to the RF signal amplification components, circuits and/or devices. According to further embodiments of the present invention, programmable bias signals may be voltage sources (e.g. V_{REF1} and V_{REF2}) when components in the power amplifier (and transmission system) are voltage biased. Programmable bias signals may adjust a bias point of the amplification components, circuits and/or devices.

According to some embodiments of the present invention, the input bias currents I_{REF1} and I_{REF2} may be generated by the bias profile generator (220A), wherein a magnitude of the input bias currents may be inversely proportional to a power amplifier input signal magnitude. According to further embodiments of the invention, the bias profile generator may generate bias currents in proportion with an output signal level control signal (V_{RAMP}), wherein a magnitude of the input bias currents may be directly proportional to the control signal.

Now turning to FIG. 2B, there is shown a block diagram of a closed loop RF power amplifier control system (200B) according to some embodiments of the present invention.

According to some embodiments of the present invention, an amplification gain of the power amplifier (210B) may be controlled by a variable supply modulator (230B). The gain of the power amplifier may be substantially proportional to a voltage output from the supply modulator (V_{PA}). According to further embodiments of the present invention, the voltage output from the supply modulator (V_{PA}) may be based on a comparison of an input voltage and a detected supply modulator output current. The supply modulator output current may be detected by a functionally associated current sense amplifier (240B) adapted to convert the detected supply modulator output current into a voltage signal.

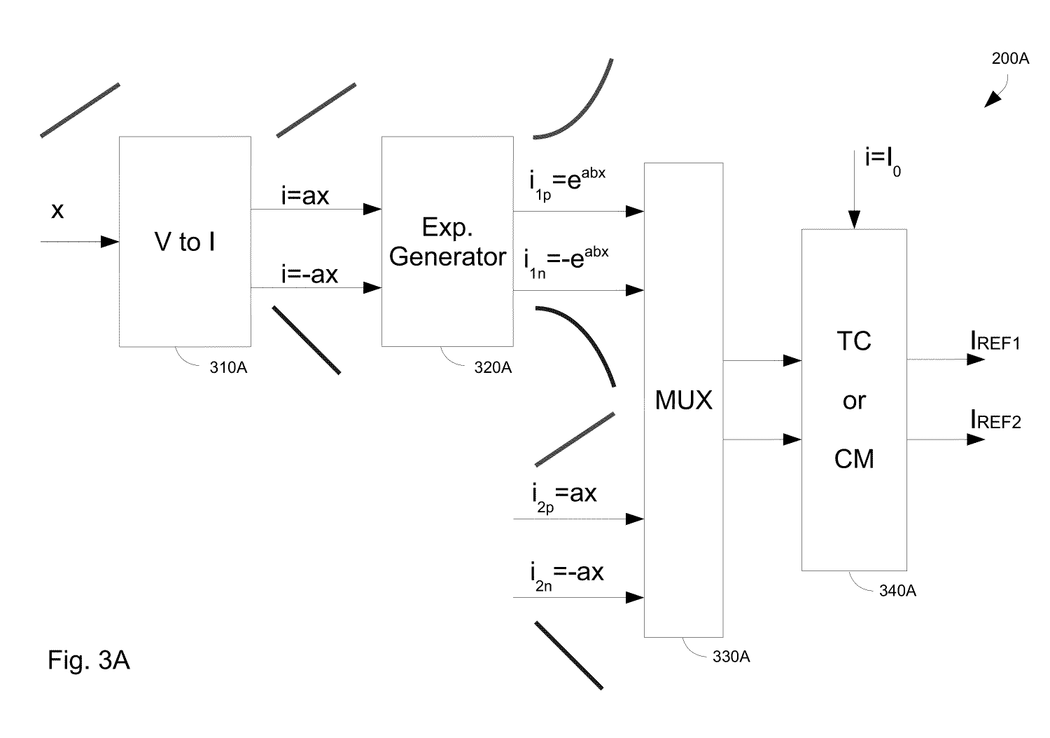

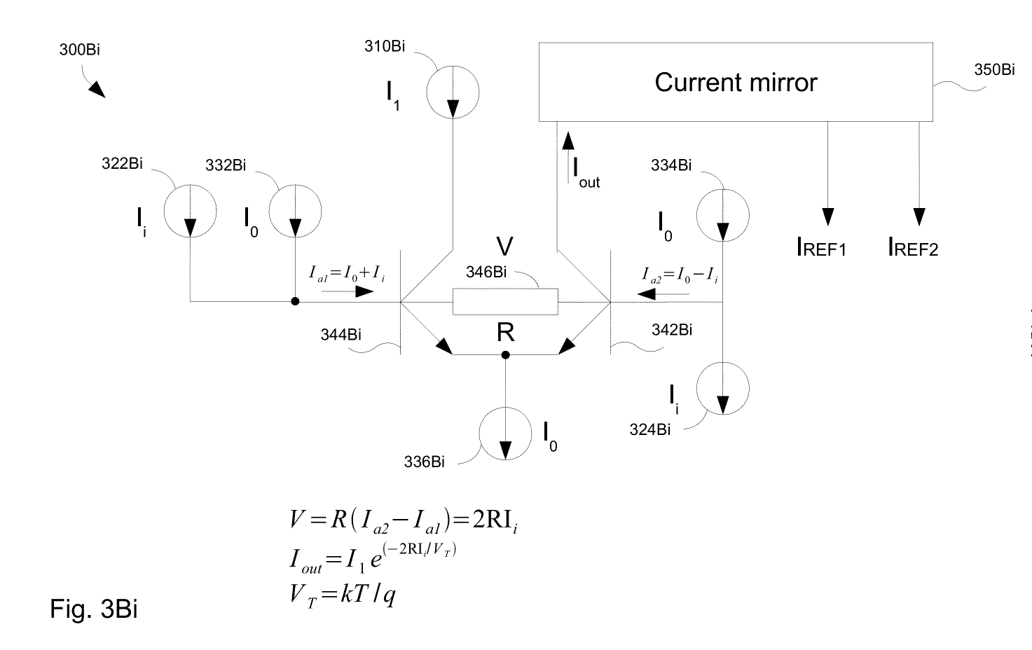

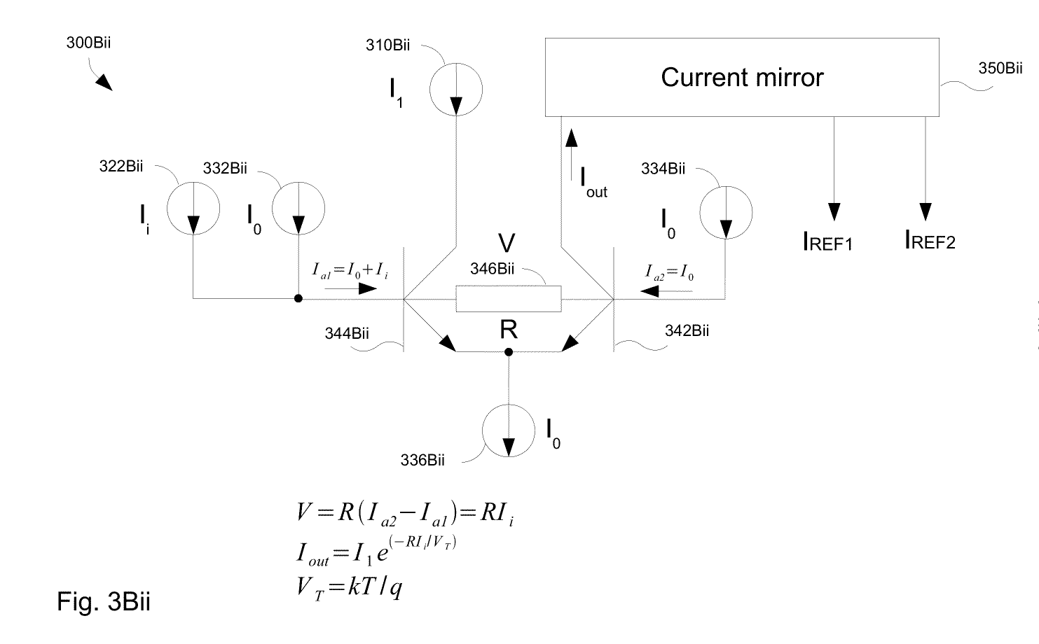

Now turning to FIG. 3A, there is shown an illustration of a bias profile generator according to some embodiments of the present invention.

According to some embodiments of the present invention, a variable input voltage may be input to a voltage to current converter (310A). According to further embodiments of the present invention, a voltage signal may be input to a high input impedance node of the voltage to current converter (310A) and a current signal may be output from a second high output impedance node of the voltage to current converter (310A). According to further embodiments of the present invention, the output current signal may be substantially independent from an operating temperature. According to further embodiments of the present invention, the voltage to current converter (310A) may employ a series-series feedback topology.

According to some embodiments of the present invention, the current signal may be multiplied by one of a plurality of predetermined constants (i.e. a or −a), thereby generating linear differential currents i₂ₚ and i₂ₙ. According to further embodiments of the present invention, the differential currents may be input to an Exponential generator (320A), thereby generating exponential differential currents i₁ₚ (e.g. i₁ₚ=e^{abx}) and i₁ₙ (e.g. i₁ₙ=−e^{abx}).

According to some embodiments of the present invention, a multiplexer (MUX—330A) may choose a set of differential currents from the group of linear and exponential differential currents. The chosen set of differential currents may be input to a translinear circuit (“TC”—340A) and/or a current mirror (“CM”—340A) along with a constant current source Jₒ for defining a reference current. The TC and/or a current mirror may generate a pair of bias currents (I_{REF1} and I_{REF2}). According to further embodiments of the present invention, a translinear circuit (“TC”—340A) may be utilized as an exponential voltage to current element and may convert an input current into an exponential output current.

According to some embodiments of the present invention, reference bias currents I_{REF1} and I_{REF2} may represent reference bias voltages V_{REF1} and V_{REF2} for biasing a functionally associated PA with a reference voltage defined operation point. According to further embodiments of the present invention, a current to voltage converter may convert reference bias currents into reference bias voltages.

Now turning to FIGS. 3Bi and 3Bii, there are shown circuit diagrams for exponential differential currents generators (300Bi and 300BII) for a current mirror and/or a translinear circuit, according to some embodiments of the present invention.

According to some embodiments of the present invention, an exponential coefficient of an output current (I_{OUT}) may be proportional to a voltage drop (V) across a resistor R (346Bi and 346Bii), e.g. Iₒᵤₜ=I₁ e^{(-RI}ᵢ^{/V}_{T}⁾. Considering an exponential relationship between a current and voltage of a base emitter junction (V_{BE}) of a transistor (342Bi and 342Bii) and that V_{BE} may be given by the voltage across the resistor R (i.e. the product between an input current source Iᵢ and the resistor R), the resulting output current I_{OUT} may be exponentially proportional to the input current.

According to some embodiments of the present invention, an input current (324Bi) may be applied to a bipolar coupled pair in a push-pull configuration (342Bi and 344Bi). The resulting voltage drop across the resistor R may be twice as great as a similar voltage drop across the resistor R in FIG. 3B ii. This voltage doubling may lead to an increased factor of 2 in the exponent of the current-voltage relationship, e.g. Iₒᵤₜ=I₁e^{(-2RI}ᵢ^{/V}_{T}⁾.

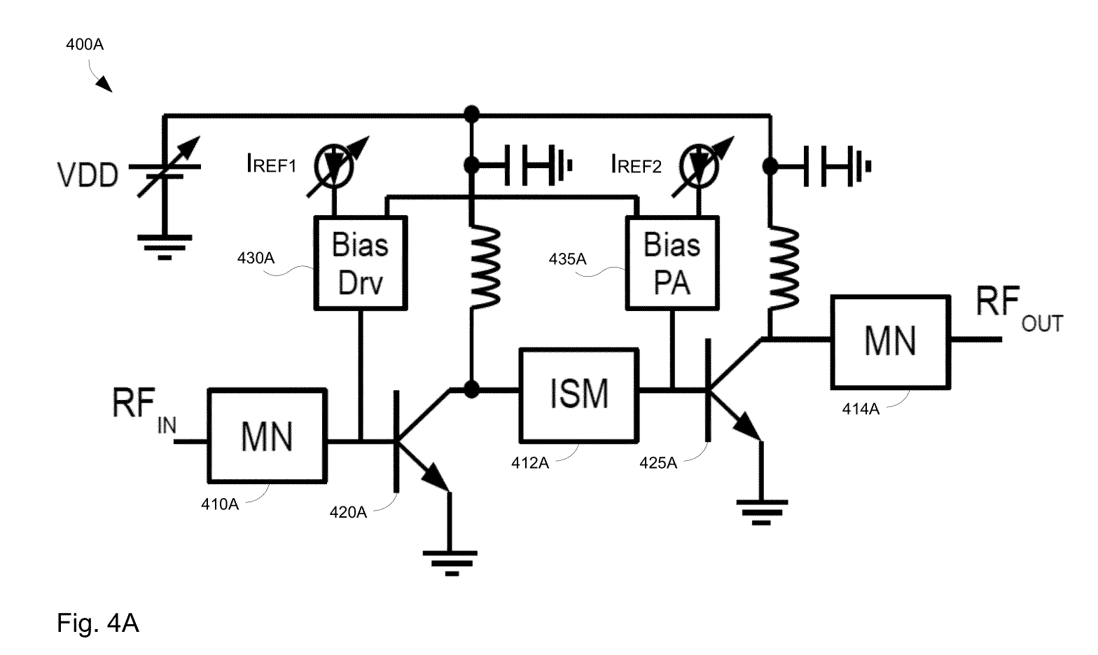

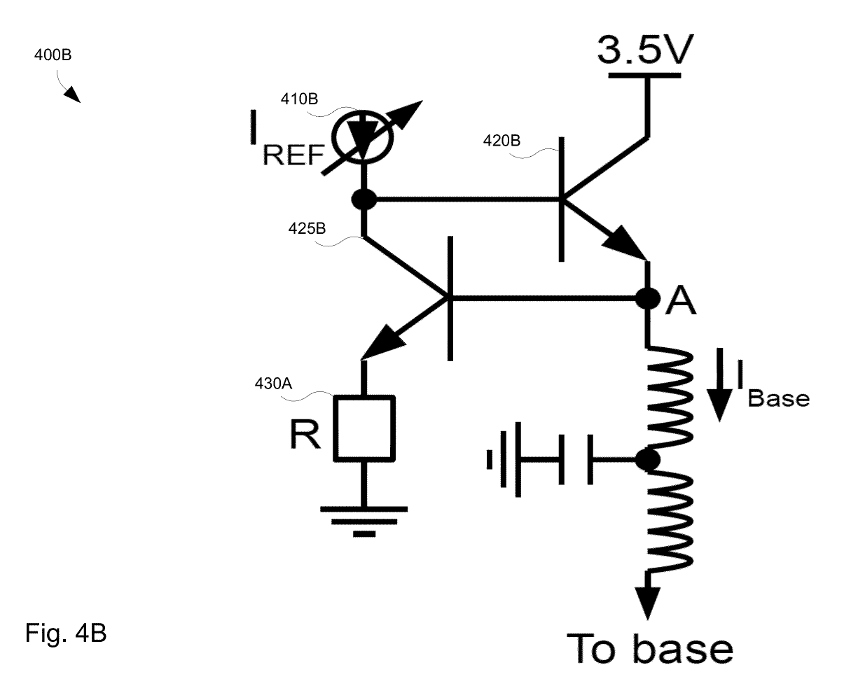

Now turning to FIG. 4A, there is shown a functional block diagram of a regulated RF power amplifier (400A) according to some embodiments of the present invention.

According to some embodiments of the present invention, a functionally associated bias profile generator may provide biasing current sources (I_{REF1} and I_{REF2}). A regulating biasing current source may be input into a driver stage (420A) through a functionally associated or integral driver bias unit (430A). A regulating biasing current source may be input into a power stage (425A) through a functionally associated or integral power stage bias unit (435A).

According to some embodiments of the present invention, the regulated RF power amplifier may receive an input signal (RF_{IN}) and output a signal through an impedance-matched network (e.g. matched networks 410A and 414A). According to further embodiments of the present invention, the signal may be biased by an output voltage of the driver bias unit and the resulting signal may be input to the driver stage of the power amplifier. According to further embodiments of the present invention, an output signal of the driver stage may be input to an inter-stage matching network (412A). According to further embodiments of the present invention, an inter-stage matching network output signal may be biased by an output voltage of the power bias unit and the resulting signal may be input to an output stage matching network to prepare the signal for output (RF_{OUT}). The inter-stage matching network (412A) may be designed for substantially maximal power transfer between the stages of the RF power amplifier in addition to substantially maximal power transfer to the output terminal (i.e. RF_{OUT}).

Now turning to FIG. 4B, there is shown a circuit diagram of a bias unit (400B) according to some embodiments of the present invention.

According to some embodiments of the present invention, the bias unit may be a current mirror (420B and 425B) adapted to bias a functionally associated driver stage and/or a power amplifier stage.

According to some embodiments of the present invention, a variable voltage-controlled biasing current source (410B—I_{REF}) may be input into the biasing unit. An output current, through low impedance node A, (I_{BASE}) may be directly proportional to I_{REF}.

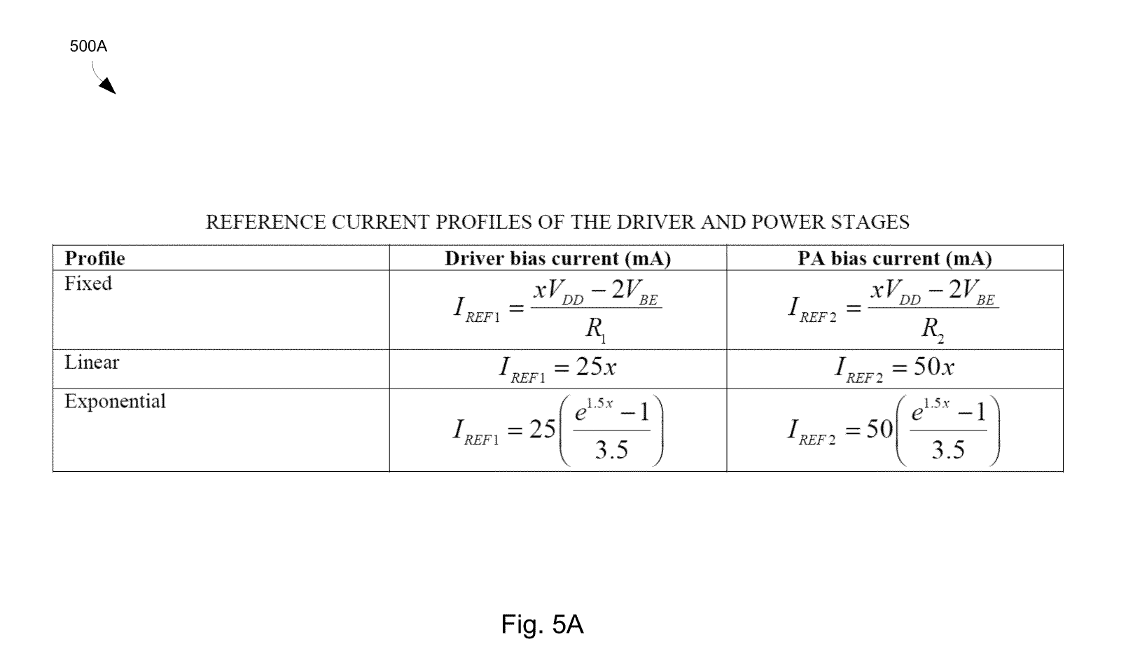

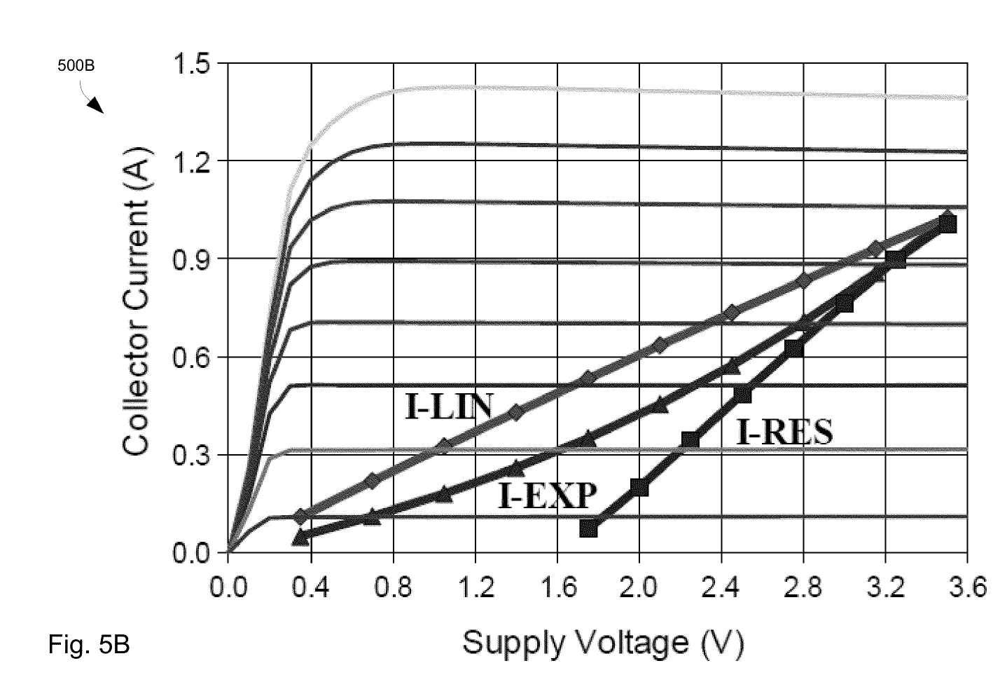

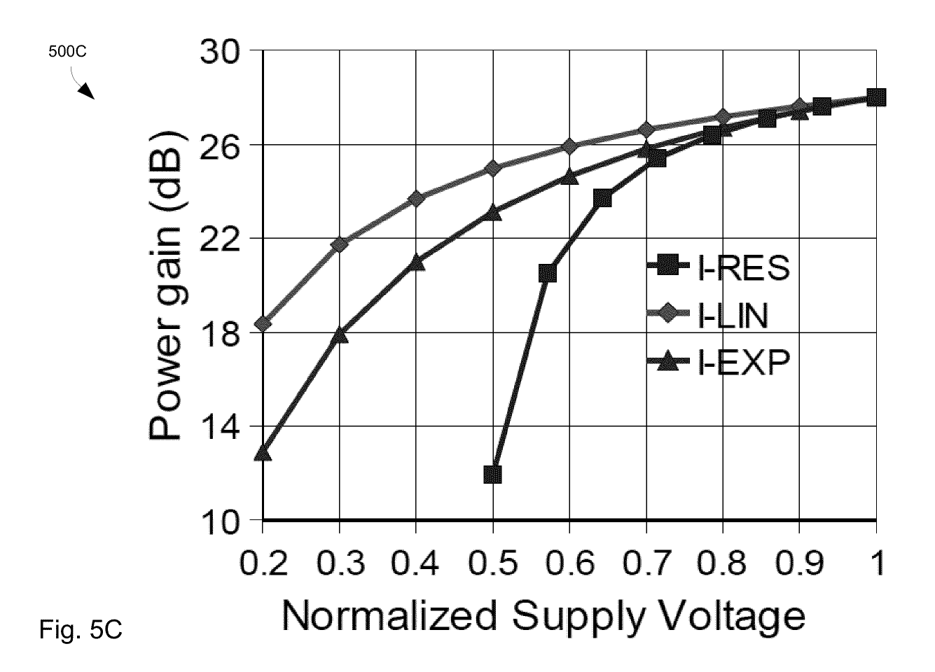

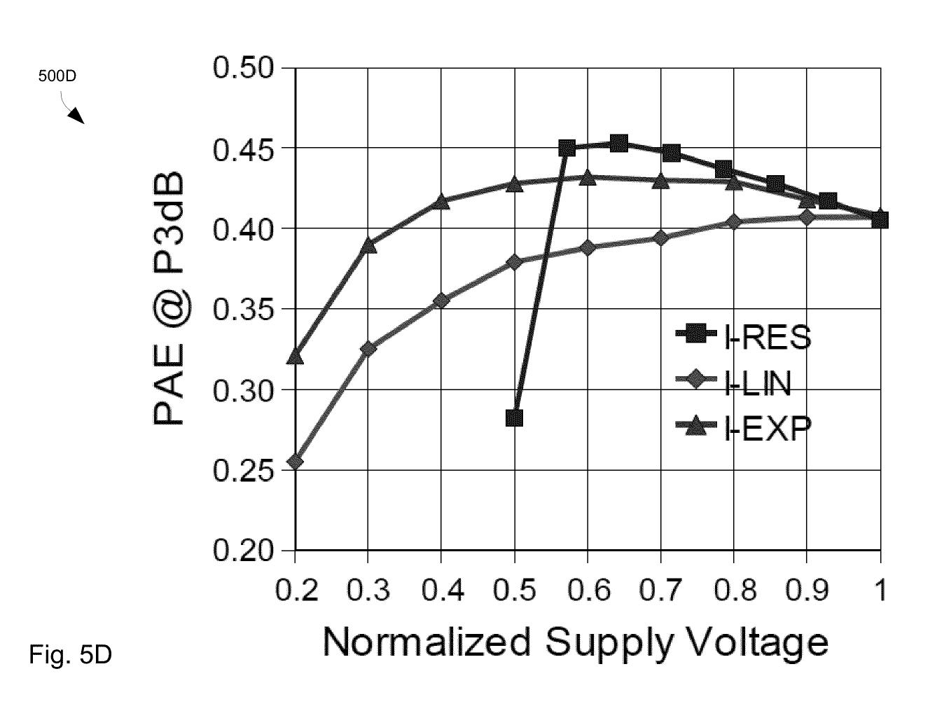

Now turning to FIG. 5A, there is shown a table of reference current profiles for biasing the driver and power stages of a power amplifier (500A) according to some embodiments of the present invention.

According to some embodiments of the present invention, a fixed profile may provide a driver bias current I_{REF1} for a functionally associated driver and a power amplifier (PA) bias current I_{REF2} for a functionally associated PA. The driver bias currents may be based on a fixed voltage to resistance relationship multiplied by a control signal. Driver bias current I_{REF1} may be a current through R₁ and PA bias current I_{REF2} may be a current through R₂.

According to some embodiments of the present invention, a linear profile may provide a driver bias current I_{REF1} for a functionally associated driver and a power amplifier (PA) bias current I_{REF2} for a functionally associated PA. The driver bias currents may be based on a coefficient multiplied by a control signal. Driver bias current I_{REF1} may be a control current multiplied by a first coefficient multiplier (e.g. 25) and PA bias current I_{REF2} may be a control current multiplied by a second coefficient multiplier (e.g. 50). Coefficient multipliers may vary according to a DC operation point of the power amplifier.

According to some embodiments of the present invention, an exponential profile may provide a driver bias current I_{REF1} for a functionally associated driver and a power amplifier (PA) bias current I_{REF2} for a functionally associated PA. The driver bias currents may be based on a coefficient multiplied by an exponential function control signal. Driver bias current I_{REF1} may be an exponential function control signal multiplied by the first coefficient multiplier (e.g. 25) and PA bias current I_{REF2} may be an exponential function control signal multiplied by the second coefficient multiplier (e.g. 50). Coefficient multipliers may vary according to a DC operation point of the power amplifier.

According to some embodiments of the present invention, reference current profiles may utilize the first coefficient multiplier (e.g. 25) for the driver and the second coefficient multiplier (e.g. 50) for the PA. Coefficient multipliers may be chosen to provide maximum reference currents for the driver (e.g. 25 mA) and for the PA (e.g. 50 mA). According to further embodiments of the present invention, the selected multipliers may provide for a biasing of the driver and PA such that the amplifier behaves as a class AB amplifier (e.g. with a maximum saturated power of +33 dBm and a power added efficiency (PAE) above 40 percent). Coefficient multipliers may vary according to a DC operation point of the power amplifier.

Now turning to FIGS. 5B-5D, there are shown experimental charts comparing reference current profiles for biasing the driver and power stages of a power amplifier according to some embodiments of the preset invention.

According to some embodiments of the present invention, device operation points may be shown for fixed (I-RES), linear (I-LIN) and exponential (I-EXP) reference current profiles (500B). According to further embodiments of the present invention, for the fixed profile (I-RES), a conduction angle of an associated current waveform may decrease with a normalized supply voltage, which results in class B amplifier operation. Gradual changes in the operation point may be obtained over a wide range of supply voltages with the linear (I-LIN) and exponential (I-EXP) reference current profiles.

According to some embodiments of the present invention, amplifier power gain may be shown for fixed (I-RES), linear (I-LIN) and exponential (I-EXP) reference current profiles (500C). According to further embodiments of the present invention, the fixed profile (I-RES) may produce low power gain at small normalized supply voltages. The linear (I-LIN) and exponential (I-EXP) reference current profiles may display a consistent power gain across a wide range of normalized supply voltages.

According to some embodiments of the present invention, amplifier power added efficiency (PAE) may be shown for fixed (I-RES), linear (I-LIN) and exponential (I-EXP) reference current profiles (500D). According to further embodiments of the present invention, the fixed profile (I-RES) may produce low PAE at small normalized supply voltages. The linear (I-LIN) and exponential (I-EXP) reference current profiles may display a consistent PAE across a wide range of normalized supply voltages. The exponential (I-EXP) reference current profile may display the greatest PAE over the widest range of normalized supply voltages.

Some embodiments of the invention, for example, may take the form of an entirely hardware embodiment, an entirely software embodiment, or an embodiment including both hardware and software elements. Some embodiments may be implemented in software, which includes but is not limited to firmware, resident software, microcode, or the like.

Furthermore, some embodiments of the invention may take the form of a computer program product accessible from a computer-usable or computer-readable medium providing program code for use by or in connection with a computer or any instruction execution system. For example, a computer-usable or computer-readable medium may be or may include any apparatus that can contain, store, communicate, propagate, or transport the program for use by or in connection with the instruction execution system, apparatus, or device.

In some embodiments, the medium may be an electronic, magnetic, optical, electromagnetic, infrared, or semiconductor system (or apparatus or device) or a propagation medium. Some demonstrative examples of a computer-readable medium may include a semiconductor or solid state memory, magnetic tape, a removable computer diskette, a random access memory (RAM), a read-only memory (ROM), a rigid magnetic disk, and an optical disk. Some demonstrative examples of optical disks include compact disk—read only memory (CD-ROM), compact disk—read/write (CD-R/W), and DVD.

In some embodiments, a data processing system suitable for storing and/or executing program code may include at least one processor coupled directly or indirectly to memory elements, for example, through a system bus. The memory elements may include, for example, local memory employed during actual execution of the program code, bulk storage, and cache memories which may provide temporary storage of at least some program code in order to reduce the number of times code must be retrieved from bulk storage during execution.

In some embodiments, input/output or I/O devices (including but not limited to keyboards, displays, pointing devices, etc.) may be coupled to the system either directly or through intervening I/O controllers. In some embodiments, network adapters may be coupled to the system to enable the data processing system to become coupled to other data processing systems or remote printers or storage devices, for example, through intervening private or public networks. In some embodiments, modems, cable modems and Ethernet cards are demonstrative examples of types of network adapters. Other suitable components may be used.

Functions, operations, components and/or features described herein with reference to one or more embodiments, may be combined with, or may be utilized in combination with, one or more other functions, operations, components and/or features described herein with reference to one or more other embodiments, or vice versa.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. A variable power amplifier (PA) module comprising:
a supply power modulator adapted to modulate supply power, within a defined range, to a power amplifier circuit responsive to a control signal; and
a bias profile generator circuit adapted to apply one or more biasing signals to one or more transistors within said power amplifier circuit such that a power efficiency level of the power amplifier circuit remains substantially stable across the defined range.

2. The PA according to claim 1, wherein the one or more biasing signals are biasing voltages.

3. The PA according to claim 2, wherein the biasing voltages are applied to one or more FET transistors within said power amplifier circuit.

4. The PA according to claim 1, wherein the one or more biasing signals are biasing currents.

5. The PA according to claim 4, wherein the biasing currents are applied to one or more BJT transistors within said power amplifier circuit.

6. The PA according to claim 1, wherein said bias profile generator circuit is further adapted to apply one or more biasing signals in proportion to the supply power modulator control signal.

7. The PA according to claim 6, wherein the proportion is a fixed value.

8. The PA according to claim 6, wherein the proportion is a linear proportion.

9. The PA according to claim 6, wherein the proportion is an exponential proportion.

10. The PA according to claim 6, wherein the bias profile generator circuit further comprises a trans-linear circuit.

11. The PA according to claim 10, wherein the proportion is a high degree polynomial function proportion.

12. The PA according to claim 1, wherein said supply power modulator is further adapted to modulate the supply power in a closed loop configuration.

13. The PA according to claim 1, wherein said supply power modulator is further adapted to modulate the supply power in an open loop configuration.

14. A bias profile generator circuit adapted to apply one or more biasing signals to one or more transistors within a power amplifier circuit such that a power efficiency level of the power amplifier circuit remains substantially stable across the defined range.

15. The bias profile generator according to claim 14, wherein the one or more biasing signals are biasing voltages.

16. The bias profile generator according to claim 15, wherein the biasing voltages are applied to one or more FET transistors within said power amplifier circuit.

17. The bias profile generator according to claim 14, wherein the one or more biasing signals are biasing currents.

18. The bias profile generator according to claim 17, wherein the biasing currents are applied to one or more BJT transistors within said power amplifier circuit.

19. The bias profile generator according to claim 14, further adapted to apply one or more biasing signals in proportion to the supply power modulator control signal.

20. The bias profile generator according to claim 19, wherein the proportion is a fixed value.

21. The bias profile generator according to claim 19, wherein the proportion is a linear proportion.

22. The bias profile generator according to claim 19, wherein the proportion is an exponential proportion.

23. The bias profile generator according to claim 19, further comprising a trans-linear circuit.

24. The bias profile generator according to claim 23, wherein the proportion is a high degree polynomial function proportion.
